(19) United States
(12) Patent Application Publication
(10) Pub. No.: US 2014/0209158 A1
(43) Pub. Date: Jul. 31, 2014

(54) SOLAR CELL

(71) Applicant: AU Optronics Corporation, Hsin-Chu (TW)

(72) Inventors: Chung-Wei LAI, HSIN-CHU (TW); Shuo-Wei LIANG, HSIN-CHU (TW)

(73) Assignee: AU Optronics Corporation, Hsin-Chu (TW)

(21) Appl. No.: 14/160,762

(22) Filed: Jan. 22, 2014

(30) Foreign Application Priority Data
Jan. 25, 2013 (CN) 201310029957.4

(51) Int. Cl. H01L 31/0224

(52) U.S. Cl. CPC H01L 31/022441
USPC 136/255

(57) ABSTRACT

A solar cell includes a crystalline silicon substrate, a plurality of P-type semiconductor material layers, a plurality of N-type semiconductor material layers, a plurality of first and second anode electric collection portions, at least one first electrode bus portion, a plurality of first and second cathode electric collection portions, at least one second electrode bus portion, and at least one third electrode bus portion. The first anode electric collection portions, the first electrode bus portion, the first cathode electric collection portions, the second electrode bus portion, the second anode electric collection portions, the second electrode bus portion, the second cathode electric collection portions, and the third electrode bus portion are arranged to form plural cell sub-units, such that an output voltage of the solar cell can be increased.

### RELATED APPLICATIONS

This application claims priority to Chinese Application Serial Number 201310029957.4, filed Jan. 25, 2013, which is herein incorporated by reference.

### BACKGROUND

1. Field of Invention

The present disclosure relates to a solar cell.

2. Description of Related Art

A solar cell may convert the energy of light directly into electricity and the solar energy is the major source. The solar cell does not produce greenhouse gas during the energy conversion, and therefore the solar cell may provide a kind of green energy benefiting the environment. Recently, since the development of the solar energy technology, the solar cells are widely utilized on the roofs of the houses or on the external walls of the buildings.

A typical solar cell has a crystalline silicon substrate, a single anode conductive portion and a single cathode conductive portion. The anode conductive portion is located on the back-light surface of the crystalline silicon substrate and electrically connects to the P-type semiconductor material of the silicon substrate. The cathode conductive portion is located on the back-light surface of the crystalline silicon substrate and electrically connects to the N-type semiconductor material of the silicon substrate. The output voltage is determined during the fabrication of the solar cell. For example, the solar cell of a single crystalline silicon substrate outputs a fixed voltage of 0.6V. If a higher output voltage is required, the solar cell module may be designed to connect several solar cells in series. However, this design may increase the volume of the module.

Besides, a normal electronic device for a 3C (Computer, Communication and Consumer electronics) product may need a power supply of high voltage (e.g. 1V) and low current. Although it may provide sufficient voltage to drive the electronic device by connecting solar cells in series, it may cause high current to damage the electronic device.

### SUMMARY

An aspect of the present invention is to provide a solar cell.

According to an embodiment of the present invention, a solar cell includes a crystalline silicon substrate, a plurality of P-type semiconductor material layers, a plurality of N-type semiconductor material layers, a plurality of first and second anode electric collection portions, at least one first electrode bus portion, a plurality of first and second cathode electric collection portions, at least one second electrode bus portion, and at least one third electrode bus portion. The crystalline silicon substrate has a light-facing surface and a back-light surface opposite to the light-facing surface. The N-type semiconductor material layers and the P-type semiconductor material layers are arranged alternately on the back-light surface of the crystalline silicon substrate. The first anode electric collection portions are arranged on the back-light surface of the crystalline silicon substrate and electrically contact at least one of the P-type semiconductor material layers respectively. The first electrode bus portion is located on the back-light surface of the crystalline silicon substrate and electrically connected to the first anode electric collection portions. The first cathode electric collection portions and the first anode electric collection portions are arranged alternately on the back-light surface of the crystalline silicon substrate. The first cathode electric collection portions electrically contact at least one of the N-type semiconductor material layers respectively. The second node electric collection portions are arranged on the back-light surface of the crystalline silicon substrate and electrically contact at least one of the P-type semiconductor material layers respectively. The second electrode bus portion is located on the back-light surface of the crystalline silicon substrate and electrically connected to the first cathode electric collection portions and the second anode electric collection portions. The second cathode electric collection portions and the second anode electric collection portions are arranged alternately on the back-light surface of the crystalline silicon substrate. The second cathode electric collection portions electrically contact at least one of the N-type semiconductor material layers respectively. The third electrode bus portion is located on the back-light surface of the crystalline silicon substrate and electrically connected to the second cathode electric collection portions.

In one or more embodiments of the present invention, the second electrode bus portion is located between the first electrode bus portion and the third electrode bus portion.

In one or more embodiments of the present invention, each of the first anode electric collection portions and each of the first cathode electric collection portions located on the back-light surface of the crystalline silicon substrate are in a substantially strip shape according to a top view.

In one or more embodiments of the present invention, the solar cell further includes a protection layer covering the P-type semiconductor material layers and the N-type semiconductor material layers. The protection layer has a plurality of anode conductive vias and a plurality of cathode conductive vias through the protection layer. The first anode electric collection portions and the second anode electric collection portions electrically contact at least one of the P-type semiconductor material layers by at least one of the anode conductive vias respectively. The first cathode electric collection portions and the second cathode electric collection portions electrically contact at least one of the N-type semiconductor material layers by at least one of the cathode conductive vias respectively.

In one or more embodiments of the present invention, the first cathode electric collection portions and the second anode electric collection portions are connected to two opposite sides of the second electrode bus portion respectively.

In one or more embodiments of the present invention, each of the second anode electric collection portions and each of the second cathode electric collection portions located on the back-light surface of the crystalline silicon substrate are in a substantially strip shape according to a top view.

In one or more embodiments of the present invention, the second electrode bus portion located on the back-light surface of the crystalline silicon substrate is in a zigzag shape according to a top view.

In one or more embodiments of the present invention, the first anode electric collection portions and the first electrode bus portion located on the back-light surface of the crystalline silicon substrate are in a substantially comb shape as a whole according to a top view.

In one or more embodiments of the present invention, the first cathode electric collection portions, the second anode electric collection portions and the second electrode bus portion located on the back-light surface of the crystalline silicon substrate are in a substantially comb shape as a whole according to a top view.

In one or more embodiments of the present invention, the second cathode electric collection portions and the third electrode bus portion located on the back-light surface of the crystalline silicon substrate are in a substantially comb shape as a whole according to a top view.

In one or more embodiments of the present invention, the shape of the anode conductive via includes round, triangle, polygon of N-edges or the combinations thereof, wherein N is a number greater than or equal to 4.

In one or more embodiments of the present invention, the shape of the cathode conductive via includes round, triangle, polygon of N-edges or the combinations thereof, wherein N is a number greater than or equal to 4.

In one or more embodiments of the present invention, the first cathode electric collection portions, the second anode electric collection portions and the second electrode bus portion located are integrated formed as a single piece.

In one or more embodiments of the present invention, the material of the crystalline silicon substrate includes single crystal silicon and polysilicon.

In one or more embodiments of the present invention, the solar cell further includes a plate. The plate is connected to the surface of the protection layer and has the first anode electric collection portions, the first electrode bus portion, the first cathode electric collection portions, the second electrode bus portion, the second anode electric collection portions, the second electrode bus portion, the second cathode electric collection portions, and the third electrode bus portion.

In one or more embodiments of the present invention, the plate is a metal plate having a plurality of isolation portions. The isolation portions are located between the third electrode bus portion and the second anode electric collection portions, between the second cathode electric collection portions and the second anode electric collection portions, between the second cathode electric collection portions and the second electrode bus portion, between the second electrode bus portion and the first anode electric collection portions, between the first cathode electric collection portions and the first anode electric collection portions, and between the first cathode electric collection portions and the first electrode bus portion.

In one or more embodiments of the present invention, the isolation portions include plastic, rubber, or a gap.

In one or more embodiments of the present invention, the solar cell is a back contact solar cell.

In one or more embodiments of the present invention, the open voltage of the solar cell is greater than or equal to 1V.

In one or more embodiments of the present invention, the output voltage of the solar cell is greater than or equal to 0.8V.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of the back-light surface of a solar cell according to one embodiment of the present invention;

FIG. 2A is a cross-section view of the solar cell along the line 2A-2A;

FIG. 2B is a cross-section view of the solar cell along the line 2A-2A according to another embodiment of the present invention;

FIG. 3 is top view of the back-light surface of the solar cell shown in FIG. 1 before the first anode electric collection portions, the first electrode bus portion, the first cathode electric collection portions, the second anode electric collection portions, the second electrode bus portion, the second cathode electric collection portions, and the third electrode bus portion are formed;

FIG. 4 is a bottom view of the solar cell according to another embodiment of the present invention;

FIG. 5 is top view of the back-light surface of the solar cell in FIG. 4 before the first anode electric collection portions, the first electrode bus portion, the first cathode electric collection portions, the second anode electric collection portions, the second electrode bus portion, the second cathode electric collection portions, and the third electrode bus portion are formed;

FIG. 6 is a top view of the back-light surface of a solar cell according to yet another embodiment of the present invention;

FIG. 7 is top view of the back-light surface of the solar cell in FIG. 6 before the first anode electric collection portions, the first electrode bus portion, the first cathode electric collection portions, the second anode electric collection portions, the second electrode bus portion, the second cathode electric collection portions, and the third electrode bus portion are formed;

FIG. 8 is an exploded view of the solar cell according to another embodiment of the present invention; and

FIG. 9 is an exploded view of the solar cell according to yet another embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

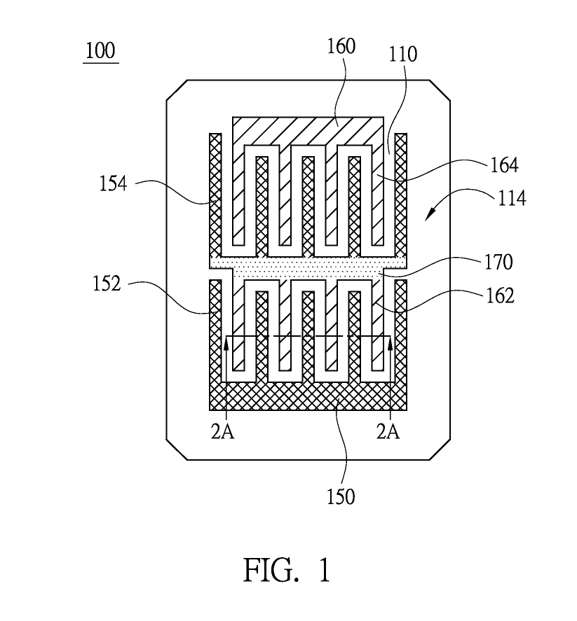

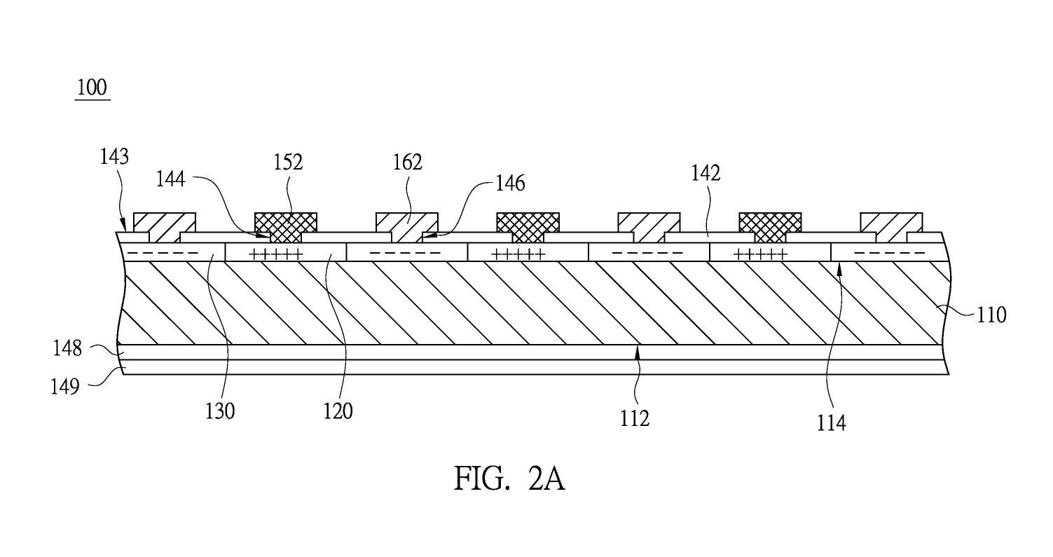

FIG. 1 is a top view of the back-light surface 114 of a solar cell 100 according to one embodiment of the present invention. FIG. 2A is a cross-section view of the solar cell 100 in FIG. 1 along the line 2A-2A. Referring to FIG. 1 and FIG. 2A, the solar cell 100 includes a crystalline silicon substrate 110, a plurality of P-type semiconductor material layers 120, a plurality of N-type semiconductor material layers 130, a plurality of first anode electric collection portions 152, a first electrode bus portion 150, a plurality of first cathode electric collection portions 162, a plurality of second anode electric collection portions 154, a second electrode bus portion 170, a plurality of second cathode electric collection portions 164, and a third electrode bus portion 160.

The crystalline silicon substrate 110 has a light-facing surface 112 and a back-light surface 114 opposite to the light-facing surface 112. The N-type semiconductor material layers 130 and the P-type semiconductor material layers 120 are arranged alternately on the back-light surface 114 of the crystalline silicon substrate 110. That is, referring to the top view, the N-type semiconductor material layers 130 and the P-type semiconductor material layers 120 are in a strip shape and arranged alternately on the back-light surface 114. The first anode electric collection portions 152 and the first cathode electric collection portions 162 are arranged alternately on the back-light surface 114 of the crystalline silicon substrate 110. The second anode electric collection portions 154 and the second cathode electric collection portions 164 are arranged alternately on the back-light surface 114 of the crystalline silicon substrate 110. Furthermore, the first electrode bus portion 150, the second electrode bus portion 170 and the third electrode bus portion 160 are located on the back-light surface 114 of the crystalline silicon substrate 110.

In this embodiment, the solar cell 100 may selectively further include a protection layer 142, 148. The protection layer 142 covers The P-type semiconductor material layers 120 and the N-type semiconductor material layers 130. The protection layer 142 has a plurality of anode conductive vias 144 and a plurality of cathode conductive vias 146 through the protection layer 142. The first anode electric collection portions 152 and the second anode electric collection portions 154 electrically contact the P-type semiconductor material layers 120 by the anode conductive via 144 respectively. The first cathode electric collection portions 162 and the second cathode electric collection portions 164 electrically contact the N-type semiconductor material layers 130 by the cathode conductive via 146 respectively. Moreover, the light-facing surface 112 of the crystalline silicon substrate 110 may be covered by an anti-reflection layer 148 and the protection layer 148. The material of the crystalline silicon substrate 110 may include single crystal silicon or polysilicon.

Moreover, in this embodiment, the solar cell 100 may be a back contact solar cell, such as an interdigitated back contact solar cell, but not tend to limit this invention. For example, FIG. 2B is a cross-section view of the solar cell 100 along the line 2A-2A according to another embodiment of the present invention. The difference between the solar cell of FIG. 2B and the solar cell of FIG. 2A is that the N-type semiconductor material layer 130 of the solar cell 100 extends from the light-facing surface 112 of the crystalline silicon substrate 110 to the back-light surface 114, and the solar cell 100 further includes a plurality of electrodes 166 through the crystalline silicon substrate 110. The electrode 166 electrically contact the first cathode electric collection portions 162 and the N-type semiconductor material layer 130, such that the electric energy generated form the light-facing surface 112 is transmitted to the first cathode electric collection portions 162. The solar cell 100 shown in FIG. 2 may be a Metal Wrap Through (MWT) solar cell.

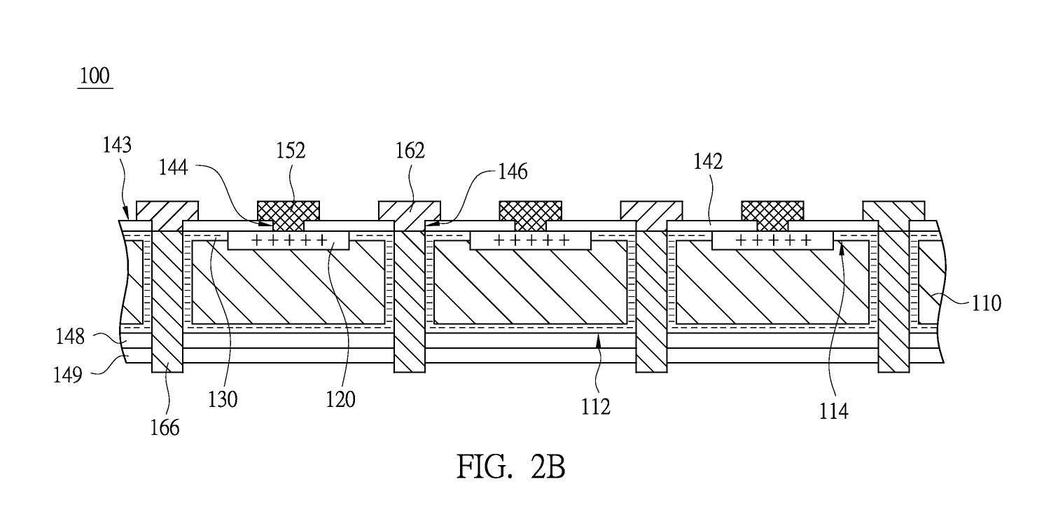

FIG. 3 is top view of the back-light surface 114 of the solar cell 100 shown in FIG. 1 before the first anode electric collection portions 152, the first electrode bus portion 150, the first cathode electric collection portions 162, the second anode electric collection portions 170, the second electrode bus portion 164, and the third electrode bus portion 160 are formed. Referring to FIG. 1, FIG. 2 and FIG. 3,the first anode electric collection portions 152 are arranged on the surface 143 of the protection layer 142. Each of the first anode electric collection portions 152 electrically contacts at least one of the P-type semiconductor material layers 120 by at least one of the anode conductive vias 144 respectively. The first electrode bus portion 150 is located on the surface 143 of the protection layer 142 and is electrically connected to the first anode electric collection portions 152.

Furthermore, the first cathode electric collection portions 162 and the first anode electric collection portions 152 are arranged alternately on the surface 143 of the protection layer 142. Each of the first cathode electric collection portions 162 electrically contacts at least one of the N-type semiconductor material layers 130 by at least one of the cathode conductive vias 146 respectively.

The second anode electric collection portions 154 are arranged on the surface 143 of the protection layer 142. The second anode electric collection portions 154 and the first anode electric collection portions 152 are extended in the same axis direction but not connected to each other. Each of the second anode electric collection portions 154 electrically contacts at least one of the P-type semiconductor material layers 120 by at least one of the anode conductive vias 144. The second electrode bus portion 170 is substantially located at the center position of the surface 143 of the protection layer 142, and is electrically connected to the first cathode electric collection portions 162 and the second anode electric collection portions 154. The first cathode electric collection portions 162 and the second anode electric collection portions 154 are connected to two opposite sides of the second electrode bus portion 170 and extend to two opposite directions respectively.

The second cathode electric collection portions 164 and the second anode electric collection portions 154 are arranged alternately on the surface 143 of the protection layer 142. The second cathode electric collection portions 164 and the first cathode electric collection portions 162 are extended in the same axis direction but not connected to each other. Each of the second cathode electric collection portions 164 electrically contacts at least one of the N-type semiconductor material layers 130 by at least one of the cathode conductive vias 146. The third electrode bus portion 160 is located on the surface 143 of the protection layer 142 and electrically connected to the second cathode electric collection portions 164. Moreover, the second electrode bus portion 170 is located between the first electrode bus portion 150 and the third electrode bus portion 160. The first electrode bus portion 150 and the third electrode bus portion 160 are adjacent to two opposite sides of the surface 143 of the protection layer 142 respectively.

Specifically, since the second electrode bus portion 170 of the solar cell 100 is electrically connected to the first cathode electric collection portions 162 and the second anode electric collection portions 154, the first anode electric collection portions 152, the first electrode bus portion 150, the first cathode electric collection portions 162 and the second electrode bus portion 170 may be regarded as a electrode of a cell sub-unit. The second anode electric collection portions 154, the second electrode bus portion 170, the second cathode electric collection portions 164 and the third electrode bus portion 160 may be regarded as another electrode of a cell sub-unit. As a result, the solar cell 100 having a single crystalline silicon substrate 110 may have the voltage utility as two conventional solar cells in series. Then, the output voltage of the solar cell 100 can be increased.

For example, when the crystalline silicon substrate 110 shown in FIG. 1 is the same as the silicon substrate of the conventional solar cell, according to the standard IEC60904 or in an illuminance of 1000 W/m2, the conventional solar cell may output a voltage of 0.6V, while the solar cell 100 shown in FIG. 1 may output a voltage of 1.2V theoretically. That is to say, twice the voltage of the conventional solar cell. According to recent technology, following the standard mentioned above, the open voltage of a solar cell having a single crystalline silicon substrate is less than or equal to 0.75V, and the output voltage is less than or equal to 0.6V. According to the experiment result of this invention, the open voltage of the solar cell 100 having a single crystalline silicon substrate 110 is substantially equal to 1V, preferably greater than 1V, and the output voltage is substantially equal to 0.8V, preferably greater than 0.8V. The difference depends on the structure of the solar cell having a single crystalline silicon substrate and the manufacturing method thereof.

Furthermore, the required voltage for a 3C electronic device is generally greater than 1V, while a lower current may prolong the lifespan thereof. Since the solar cell 100 lifts the output voltage and the output current of the solar cell 100 is decreased, such that the solar cell 100 may be utilized in various 3C electronic products widely. When the solar cell module with a specific output voltage is manufactured, it is not necessary to connect several solar cells in series to increase the output voltage. Therefore, the assembly of the solar module becomes more flexible so that the space of the solar cell module and the material cost are significantly reduced.

Furthermore, the anterior process for the fabrication of the solar cell 100 is maintained. The output voltage may be modified by controlling the quantities of the first anode electric collection portions 152, the first electrode bus portion 150, the first cathode electric collection portions 162, the second anode electric collection portions 154, the second electrode bus portion 170, the second cathode electric collection portions 164, and the third electrode bus portion 160. As a result, the solar cell 100 has the characteristic of high output voltage.

In this embodiment, each of the first anode electric collection portions 152, each of the second anode electric collection portions 154, each of the first cathode electric collection portions 162, each of the second cathode electric collection portions 164, the first electrode bus portion 150, the second electrode bus portion 170, and the third electrode bus portion 160 are all in a strip shape on the back-light surface 114 of the crystalline silicon substrate 110 according to a top view. However, the shape thereof is not limited to strip. Moreover, the first anode electric collection portions 152 and the first electrode bus portion 150 located on the back-light surface 114 of the crystalline silicon substrate 110 are in a substantially comb shape as a whole according to a top view. The first cathode electric collection portions 162, the second anode electric collection portions 154 and the second electrode bus portion 170 located on the back-light surface 114 of the crystalline silicon substrate 110 are in a substantially comb shape as a whole according to a top view. Also, the second cathode electric collection portions 164 and the third electrode bus portion 160 located on the back-light surface 114 of the crystalline silicon substrate 110 are in a substantially comb shape as a whole according to a top view. However, the shape thereof is not limited to comb.

Furthermore, in this embodiment, the anode conductive via 144 and the cathode conductive via 146 are in a round shape. However, in other embodiments of the present invention, the shape of the anode conductive via 144 may include round, triangle, polygon of N-edges or the combinations thereof, and the shape of the cathode conductive via 146 may also include round, triangle, polygon of N-edges or the combinations thereof. N is a number greater than or equal to 4.

The first anode electric collection portions 152, the first electrode bus portion 150, the first cathode electric collection portions 162, the second anode electric collection portions 154, the second electrode bus portion 170, the second cathode electric collection portions 164, and the third electrode bus portion 160 may be formed on the protection layer 142 of the crystalline silicon substrate 110 by screen printing metal (e.g., copper) layers. As a result, the first cathode electric collection portions 162, the second anode electric collection portions 154, and the second electrode bus portion 170 may be integrated formed as a single piece, the second cathode electric collection portions 164 and the third electrode bus portion 160 may be integrated formed as a single piece, and the first anode electric collection portions 152 and the first electrode bus portion 150 may be integrated formed as a single piece, but the present invention is not limited in this regard. For example, the first cathode electric collection portions 162, the second anode electric collection portions 154, and the second electrode bus portion 170 may be connected to each other by soldering.

It should be understood that the components and the materials described above will not be repeated in the following description. In the following description, the solar cell in other type will be explained.

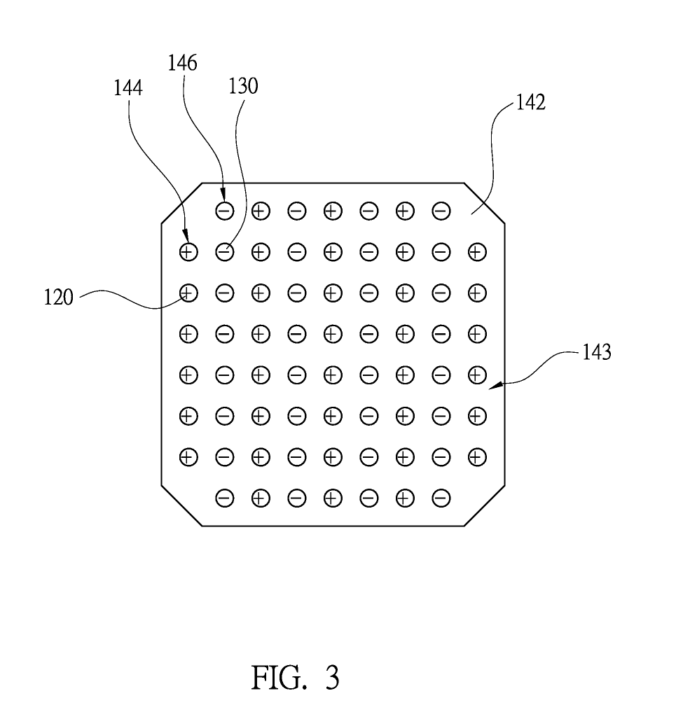

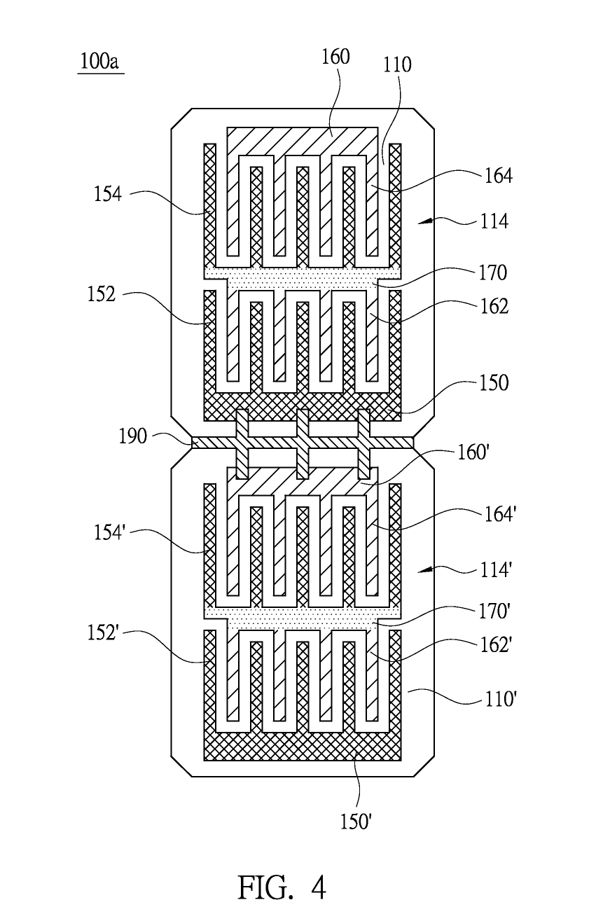

FIG. 4 is a bottom view of the solar cell 100a according to another embodiment of the present invention. FIG. 5 is top view of the back-light surface 114, 114′ of the solar cell 100a in FIG. 4 before the first anode electric collection portions 152, 152′, the first electrode bus portions 150, 150′, the first cathode electric collection portions 162, 162′, the second anode electric collection portions 154, 154′, the second electrode bus portions 170, 170′, the second cathode electric collection portions 164, 164′, and the third electrode bus portions 160, 160′are formed. Referring to FIG. 4 and FIG. 5, the solar cell 100a includes crystalline silicon substrates 110, 110′, a plurality of P-type semiconductor material layers 120, 120′, a plurality of N-type semiconductor material layers 130, 130′, protection layers 142, 142′, a plurality of first anode electric collection portions 152, 152′, first electrode bus portions 150, 150′, a plurality of first cathode electric collection portions 162, 162′, a plurality of second anode electric collection portions 154, 154′, second electrode bus portions 170, 170′, a plurality of second cathode electric collection portions 164, 164′, and third electrode bus portions 160, 160′.

The difference from the embodiment shown in FIG. 1 is that the solar cell 100a has two crystalline silicon substrates 100, 100′ and a soldering band 190. The first electrode bus portion 150 located on the crystalline silicon substrates 110 is electrically connected to the third electrode bus portion 160′ located on the crystalline silicon substrate 100′ by the soldering band 190. Accordingly, the solar cell 100a may be regarded as four sets of cell sub-units in series, and its output voltage is greater than that of the solar cell 100 (shown in FIG. 1).

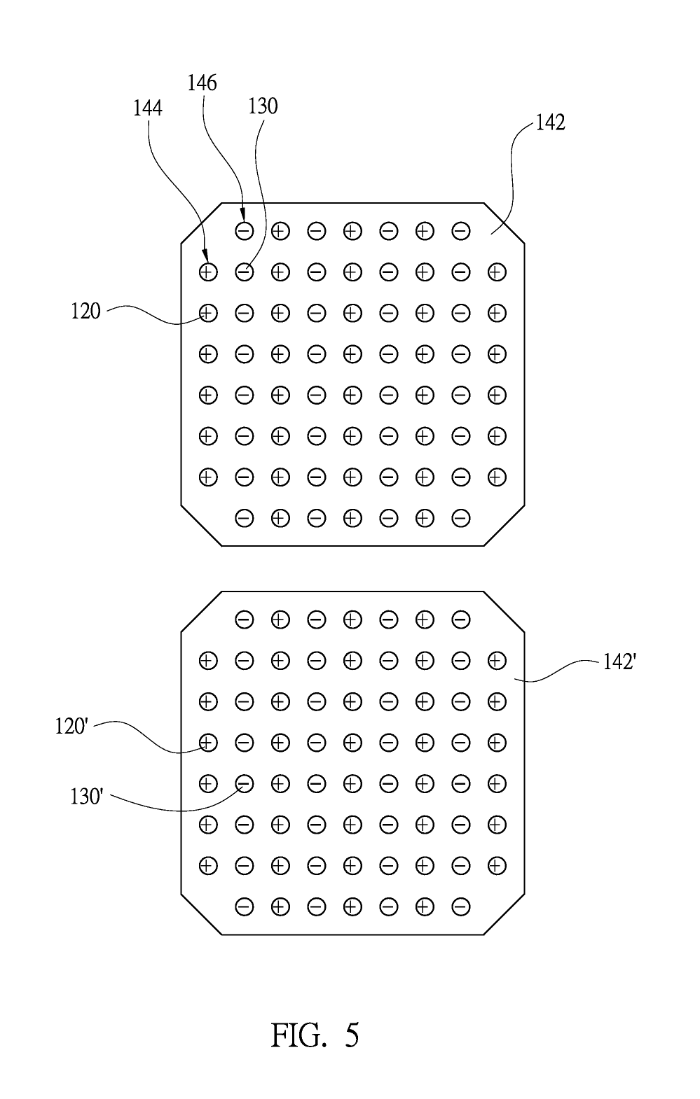

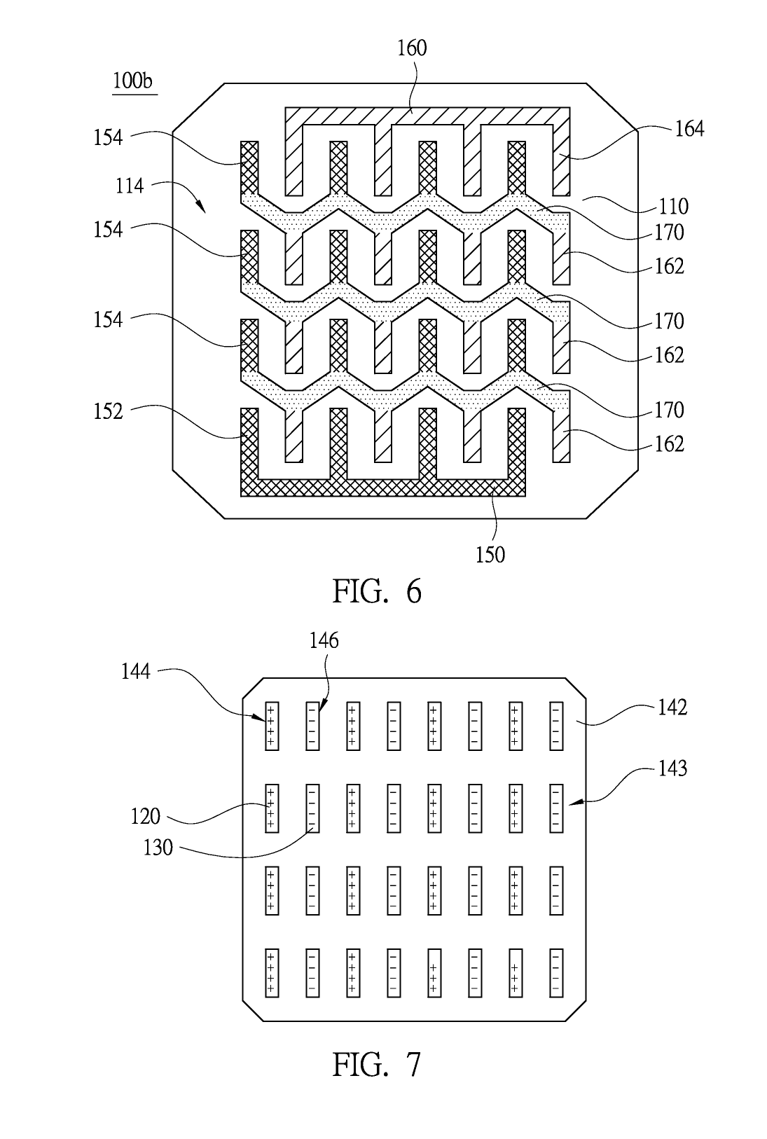

FIG. 6 is a top view of the back-light surface 114 of a solar cell 100b according to yet another embodiment of the present invention. FIG. 7 is top view of the back-light surface 114 of the solar cell 100b in FIG. 6 before the first anode electric collection portions 152, the first electrode bus portion 150, the first cathode electric collection portions 162, the second anode electric collection portions 154, the second electrode bus portion 170, the second cathode electric collection portions 164, and the third electrode bus portion 160 are formed. Referring to FIG. 6 and FIG. 7, the solar cell 100b includes a crystalline silicon substrate 110, a plurality of P-type semiconductor material layers 120, a plurality of N-type semiconductor material layers 130, protection layers 142, a plurality of first anode electric collection portions 152, a first electrode bus portion 150, a plurality of first cathode electric collection portions 162, a plurality of second anode electric collection portions 154, a second electrode bus portion 170, a plurality of second cathode electric collection portions 164, and a third electrode bus portions 160.

The difference from the embodiment shown in FIG. 1 is that the quantities of the first cathode electric collection portions 162, the second anode electric collection portions 154, and the second electrode bus portion 170 is more than that of the solar cell shown in FIG. 1. The second electrode bus portion 170 located on the back-light surface 114 of the crystalline silicon substrate 110 is in a zigzag shape according to a top view. Moreover, the anode conductive via 144 and the cathode conductive via 146 are in the shape of quadrilateral or strip. In this embodiment, the solar cell 100b has four sets of cell sub-units in series, and its output voltage is greater than that of the solar cell 100 (shown in FIG. 1).

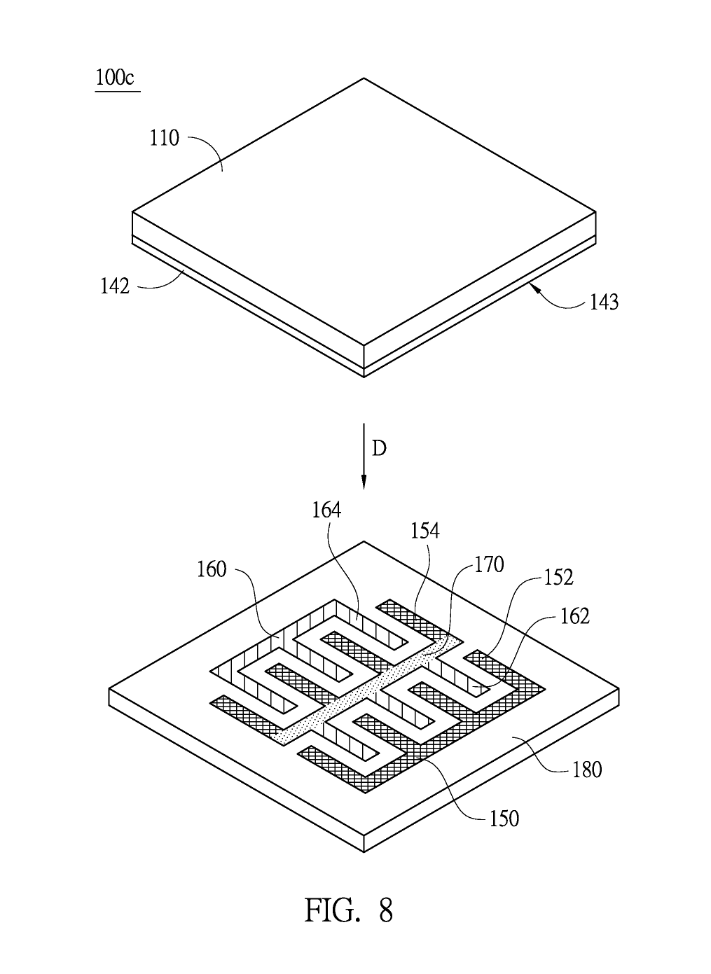

FIG. 8 is an exploded view of the solar cell 100c according to another embodiment of the present invention. The difference from the embodiment in FIG. 1 is that the solar cell 100c further includes a plate 180. The plate 180 may be a print circuit board (PCB) having a plurality of first anode electric collection portions 152, a first electrode bus portion 150, a plurality of first cathode electric collection portions 162, a plurality of second anode electric collection portions 154, a second electrode bus portion 170, a plurality of second cathode electric collection portions 164, and a third electrode bus portions 160. When the crystalline silicon substrate 110 is positioned to the plate 180 in the direction D, the plate 180 contacts the surface 143 of the protection layer 142, such that the first anode electric collection portions 152 and the second anode electric collection portions 154 electrically contact the P-type semiconductor material layers 120 (shown in FIG. 2A), and the first cathode electric collection portions 162 and the second cathode electric collection portions 164 electrically contact the N-type semiconductor material layers 130 (shown in FIG. 2A).

In this embodiment, the solar cell 100c may be regarded as two sets of cell sub-units in series.

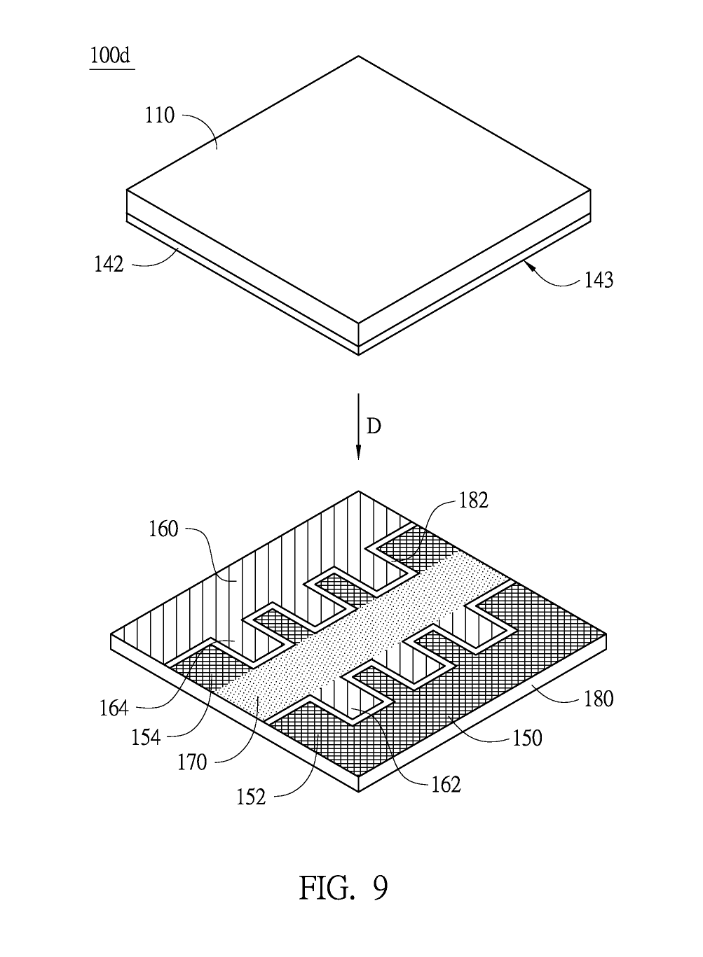

FIG. 9 is an exploded view of the solar cell 100d according to yet another embodiment of the present invention. The difference from the embodiment shown in FIG. 1 is that the plate 180 is a metal plate having a plurality of isolation portions 182. The isolation portions 182 are located between the third electrode bus portion 160 and the second anode electric collection portions 154, between the second cathode electric collection portions 164 and the second anode electric collection portions 154, between the second cathode electric collection portions 164 and the second electrode bus portion 170, between the second electrode bus portion 170 and the first anode electric collection portions 152, and between the first cathode electric collection portions 162 and the first anode electric collection portions 150. The material of the isolation portions 182 may include plastic, rubber, or the isolation portions 182 may be designed as a gap having electric insulation effect.

In this embodiment, the solar cell 100d may be regarded as two sets of cell sub-units in series.

Comparing the solar cell of the present invention with the conventional one, since the second electrode bus portion is electrically connected to the first cathode electric collection portions and the second anode electric collection portions, the first anode electric collection portions, the first electrode bus portion, the first cathode electric collection portions and the second electrode bus portion may be regarded as a cell sub-unit. The second anode electric collection portions, the second electrode bus portion, the second cathode electric collection portions and the third electrode bus portion may be regarded as another cell sub-unit. As a result, the solar cell having a single crystalline silicon substrate has the voltage of two solar cells in series so that the output voltage of the solar cell can be lifted.

Furthermore, the anterior process for the fabrication of the solar cell is maintained. The output voltage may be modified by controlling the quantities of the first anode electric collection portions, the first electrode bus portion, the first cathode electric collection portions, the second anode electric collection portions, the second electrode bus portion, the second cathode electric collection portions, and the third electrode bus portion, such that the solar cell may be utilized in 3C electronic products. For the fabrication of the solar cell module with a specific output voltage, it is not necessary to connect several solar cells in series to increase the output voltage. Therefore, the space of the solar cell module and the material cost are significantly decreased. The design of this invention decreases the output current to prevent the product from damaging by the high current.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A solar cell, comprising:
a crystalline silicon substrate having a light-facing surface and a back-light surface that is opposite to the light-facing surface;
a plurality of P-type semiconductor material layers;
a plurality of N-type semiconductor material layers, wherein the N-type semiconductor material layers and the P-type semiconductor material layers are arranged alternately on the back-light surface of the crystalline silicon substrate;
a plurality of first anode electric collection portions arranged on the back-light surface of the crystalline silicon substrate and electrically contacting at least one of the P-type semiconductor material layers respectively;
at least one first electrode bus portion located on the back-light surface of the crystalline silicon substrate and electrically connected to the first anode electric collection portions;
a plurality of first cathode electric collection portions, wherein the first cathode electric collection portions and the first anode electric collection portions are arranged alternately on the back-light surface of the crystalline silicon substrate and electrically contacting at least one of the N-type semiconductor material layers respectively;
a plurality of second anode electric collection portions arranged on the back-light surface of the crystalline silicon substrate and electrically contacting at least one of the P-type semiconductor material layers respectively;
at least one second electrode bus portion located on the back-light surface of the crystalline silicon substrate and electrically contacting the first cathode electric collection portions and the second anode electric collection portions;
a plurality of second cathode electric collection portions, wherein the second cathode electric collection portions and the second anode electric collection portions are arranged alternately on the back-light surface of the crystalline silicon substrate and electrically connected to at least one of the N-type semiconductor material layers respectively; and
at least one third electrode bus portion located on the back-light surface of the crystalline silicon substrate and electrically connected to the second cathode electric collection portions.

2. The solar cell of claim 1, wherein the second electrode bus portion is located between the first electrode bus portion and the third electrode bus portion.

3. The solar cell of claim 1, wherein each of the first anode electric collection portions and each of the first cathode electric collection portions located on the back-light surface of the crystalline silicon substrate are in a substantially strip shape according to a top view.

4. The solar cell of claim 1, further comprising:
a protection layer covering the P-type semiconductor material layers and the N-type semiconductor material layers, wherein the protection layer has a plurality of anode conductive vias and a plurality of cathode conductive vias through the protection layer, the first anode electric collection portions and the second anode electric collection portions electrically contact at least one of the P-type semiconductor material layers by at least one of the anode conductive vias respectively, and the first cathode electric collection portions and the second cathode electric collection portions electrically contact at least one of the N-type semiconductor material layers by at least one of the cathode conductive vias respectively.

5. The solar cell of claim 1, wherein the first cathode electric collection portions and the second anode electric collection portions are connected to two opposite sides of the second electrode bus portion respectively.

6. The solar cell of claim 1, wherein each of the second anode electric collection portions and each of the second cathode electric collection portions located on the back-light surface of the crystalline silicon substrate are in a substantially strip shape according to a top view.

7. The solar cell of claim 1, wherein the second electrode bus portion located on the back-light surface of the crystalline silicon substrate is in a zigzag shape according to a top view.

8. The solar cell of claim 1, wherein the first anode electric collection portions and the first electrode bus portion located on the back-light surface of the crystalline silicon substrate are in a substantially comb shape as a whole according to a top view.

9. The solar cell of claim 1, wherein the first cathode electric collection portions, the second anode electric collection portions and the second electrode bus portion located on the back-light surface of the crystalline silicon substrate are in a substantially comb shape as a whole according to a top view.

10. The solar cell of claim 1, wherein the second cathode electric collection portions and the third electrode bus portion located on the back-light surface of the crystalline silicon substrate are in a substantially comb shape as a whole according to a top view.

11. The solar cell of claim 4, wherein the shape of the anode conductive via includes round, triangle, polygon of N-edges or the combinations thereof, wherein N is a number greater than or equal to 4.

12. The solar cell of claim 4, wherein the shape of the cathode conductive via includes round, triangle, polygon of N-edges or the combinations thereof, wherein N is a number greater than or equal to 4.

13. The solar cell of claim 1, wherein the first cathode electric collection portions, the second anode electric collection portions and the second electrode bus portion located are integrated formed as a single piece.

14. The solar cell of claim 1, wherein the material of the crystalline silicon substrate includes single crystal silicon and polysilicon.

15. The solar cell of claim 4, further comprising:
a plate connected to the surface of the protection layer and having the first anode electric collection portions, the first electrode bus portion, the first cathode electric collection portions, the second electrode bus portion, the second anode electric collection portions, the second electrode bus portion, the second cathode electric collection portions, and the third electrode bus portion.

16. The solar cell of claim 15, wherein the plate is a metal plate having a plurality of isolation portions, the isolation portions are located between the third electrode bus portion and the second anode electric collection portions, between the second cathode electric collection portions and the second anode electric collection portions, between the second cathode electric collection portions and the second electrode bus portion, between the second electrode bus portion and the first anode electric collection portions, between the first cathode electric collection portions and the first anode electric collection portions, and between the first cathode electric collection portions and the first electrode bus portion.

17. The solar cell of claim 16, wherein the isolation portions include plastic, rubber, or a gap.

18. The solar cell of claim 1, wherein the solar cell is a back contact solar cell.

19. The solar cell of claim 1, wherein an open voltage of the solar cell is greater than or equal to 1V.

20. The solar cell of claim 1, wherein an output voltage of the solar cell is greater than or equal to 0.8V.
